(19) United States
(12) Patent Application Publication
(10) Pub. No.: US 2022/0196854 A1
(43) Pub. Date: Jun. 23, 2022

(54) ELECTRONIC BLACKBODY MATERIAL AND ELECTRON DETECTOR

(71) Applicants: Tsinghua University, Beijing (CN); HON HAI PRECISION INDUSTRY CO., LTD., New Taipei (TW)

(72) Inventors: KE ZHANG, Beijing (CN); GUO CHEN, Beijing (CN); PENG LIU, Beijing (CN); KAI-LI JIANG, Beijing (CN); SHOU-SHAN FAN, Beijing (CN)

(21) Appl. No.: 17/225,721

(22) Filed: Apr. 8, 2021

(30) Foreign Application Priority Data
Dec. 17, 2020 (CN) 202011497805.3

(51) Int. Cl. G01T 1/16; B82Y 30/00

(52) U.S. Cl. CPC G01T 1/1606; B82Y 30/00

(57) ABSTRACT

An electron blackbody material is provided. The electron blackbody material is a porous carbon layer. The porous carbon layer consists of a plurality of carbon material particles and a plurality of micro gaps, the plurality of micro gaps are located between the plurality of carbon material particles. An electron detector using the electron blackbody material is also provided.

This application claims all benefits accruing under 35 U.S.C. § 119 from China Patent Application No. 202011497805.3, filed on Dec. 17, 2020, in the China Intellectual Property Office, the contents of which are hereby incorporated by reference. The application is also related to copending applications entitled, “ELECTRON BEAM DETECTION DEVICE AND METHOD FOR DETECTING ELECTRON BEAM USING THE SAME,” filed ______ (Atty. Docket No. US82853); “ELECTRONIC BLACKBODY CAVITY AND SECONDARY ELECTRON DETECTION DEVICE USING THE SAME,” filed ______ (Atty. Docket No. US82854); “SECONDARY ELECTRON PROBE AND SECONDARY ELECTRON DETECTOR,” filed ______ (Atty. Docket No. US82855); “METHOD FOR MAKING ELECTRONIC BLACKBODY STRUCTURE AND ELECTRONIC BLACKBODY STRUCTURE”, filed ______ (Atty. Docket No. US82856); “DEVICE AND METHOD FOR MEASURING ELECTRON BEAM,” filed ______ (Atty. Docket No. US83296).

### FIELD

The present disclosure relates to an electronic blackbody material and an electron detector.

### BACKGROUND

Electron-absorbing components are often required to absorb electrons in fields of microelectronics technology. Metals are usually used to absorb electrons. However, when the metals are used to absorb electrons, a large number of electrons are reflected or transmitted on a surface of the metals and cannot be absorbed by the metals. Therefore, an absorption efficiency of electrons is low.

At present, there is no material that can absorb nearly 100% of electrons. Such a novel material is referred as an electronic blackbody material. Therefore, designing an electronic blackbody structure with an absorption rate of almost 100% is greatly desired within the art

### BRIEF DESCRIPTION OF THE DRAWINGS

Implementations of the present technology will now be described, by way of example only, with reference to the attached figures, wherein:

FIG. 1 is a schematic diagram of an electron detector according to one embodiment.

FIG. 2 shows electron absorption rate comparison diagrams between the electronic blackbody structure provided by one embodiment of the present disclosure and other materials.

FIG. 3 shows an electron absorption rate of a super-aligned carbon nanotube array vs. a height of the super-aligned carbon nanotube array.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean “at least one.”

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature which is described, such that the component need not be exactly or strictly conforming to such a feature. The term “comprise,” when utilized, means “include, but not necessarily limited to”; it specifically indicates open-ended inclusion or membership in the so-described combination, group, series, and the like.

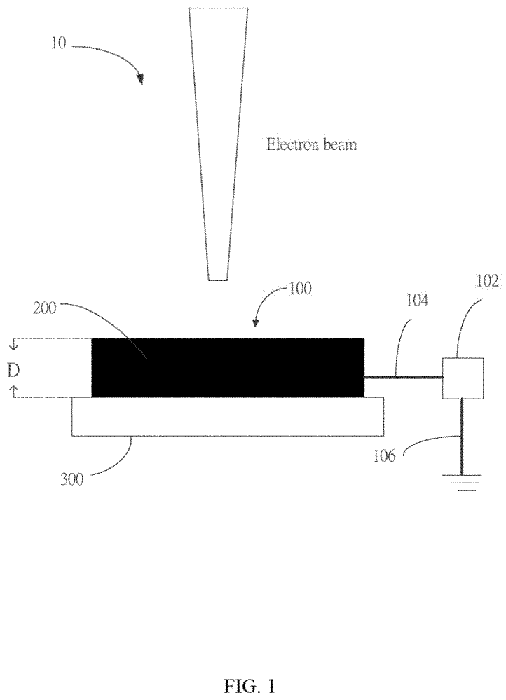

Referring to FIG. 1, an electron detector 10 according to one embodiment is provided. The electron detector 10 comprises an electron detecting element 102 and an electron absorbing element 100. The electron detecting element 102 comprises a first terminal 104 and a second terminal 106. The first terminal 104 is electrically connected to the electron absorbing element 100, the second terminal 106 is grounded. A material of the electron absorbing element 100 is a porous carbon layer 200.

The porous carbon layer 200 comprises a plurality of carbon particles, and there are a plurality of micro gaps between the plurality of carbon particles. The size of each of the plurality of micro gaps is in nanoscale or microscale. The term “nanoscale” means that the size of each of the plurality of micro gaps is less than or equal to 1000 nanometers, and the term “microscale” means that the size of each of the plurality of micro gaps is less than or equal to 1000 micrometers. In some embodiments, the term “nanoscale” means that the size of each of the plurality of micro gaps is less than or equal to 100 nanometers, and the term “microscale” means that the size of each of the plurality of micro gaps is less than or equal to 100 micrometers.

The porous carbon layer 200 only consists of a plurality of carbon particles without other impurities; and the plurality of carbon particles consist of carbon atoms.

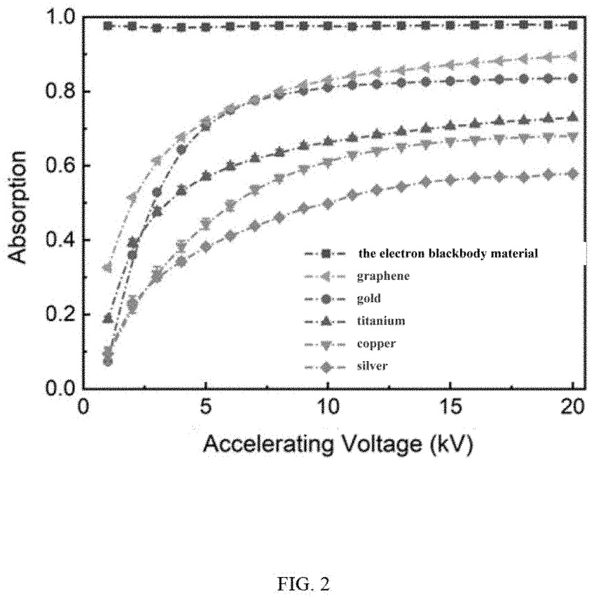

The porous carbon layer 200 is an electronic blackbody material layer. There are nanoscale or microscale gaps between the plurality of carbon material particles in the porous carbon layer 200. After the electrons enter the electronic blackbody material, they will be multiplied refracted and reflected in the plurality of micro gaps, and are finally absorbed by the porous carbon layer 200. The electrons cannot be emitted out from the electronic blackbody material. The electron blackbody material has an electron absorption rate higher than 95%, and can even reach 100%. In other words, the electronic blackbody material can be regarded as an absolute blackbody of electrons. Referring to FIG. 2, compared with traditional metal materials and graphite that are used to absorb electrons, the electron blackbody material provided by the embodiment of the present invention has an electron absorption rate of almost 100%.

The carbon particles comprise at least one of linear particles and spherical particles. A maximum diameter of a cross section of the linear particles is less than or equal to 1000 micrometers. The linear particles can be carbon fibers, carbon microwires, carbon nanotubes, and the like. A maximum diameter of the spherical particles is less than or equal to 1000 microns. The spherical particles can be carbon nanospheres or carbon microspheres. When the electrons hits a surface of the porous carbon layer 200, since the porous carbon layer 200 comprises the plurality of micro pores, most of the electrons get into the plurality of micro pores of the porous carbon layer 200, and are absorbed by the porous carbon layer 200. Even if a small part of the electrons cannot be absorbed immediately, since the porous carbon layer 200 is composed of linear particles and/or spherical particles, and surfaces of the linear particles and/or spherical particles are curved, the small part of electrons will be reflected by the curved surfaces to the inside of the porous carbon layer 200, and finally absorbed by the porous carbon layer 200.

In one embodiment, the plurality of carbon particles are a plurality of carbon nanotubes, and the porous carbon layer 200 is a carbon nanotube structure. In one embodiment, the carbon nanotube structure is a pure carbon nanotube structure, the pure carbon nanotube structure means that the carbon nanotube structure only consists of carbon nanotubes without other impurities, and the carbon nanotubes are also pure carbon nanotubes. The carbon nanotube structure is a carbon nanotube array or a carbon nanotube network structure.

In one embodiment, the carbon nanotube structure is the carbon nanotube array, and the carbon nanotube array can be located on an insulating substrate. There is a crossing angle between an extending direction of the carbon nanotubes of the carbon nanotube array and the insulating substrate. The crossing angle is greater than 0 degrees and less than or equal to 90 degrees. The crossing angle is more conducive to the plurality of micro gaps in the carbon nanotube array to prevent the secondary emitted from the carbon nanotube array, to improve the absorption rate of the carbon nanotube array for secondary electrons; and thereby improving the detection accuracy of secondary electrons. In one embodiment, the carbon nanotube array can be directly grown on the insulating substrate. In another embodiment, the carbon nanotube array is grown on a growing substrate, the carbon nanotube array comprises a top surface and a bottom surface, and the bottom surface is connected to the growing substrate; and then the carbon nanotube array on the growing substrate is turned over and transferred to the insulating substrate to used as the porous carbon layer 200, and the top surface of the carbon nanotube array is connected with the insulating substrate.

In one embodiment, the carbon nanotube structure is a super-aligned carbon nanotube array, and the super-aligned carbon nanotube array is located on the insulating substrate. The super-aligned carbon nanotube array can be grown directly on the insulating substrate; the super-aligned carbon nanotube array can also be transferred from its growth substrate to the insulating substrate. The super-aligned carbon nanotube array comprises a plurality of carbon nanotubes parallel to each other and perpendicular to the insulating substrate. A minority of the plurality of carbon nanotubes in the carbon nanotube array may be randomly aligned. However, the number of randomly aligned carbon nanotubes is very small and does not affect the overall oriented alignment of the majority of the plurality of carbon nanotubes in the carbon nanotube array. The super-aligned carbon nanotube array is free with impurities, such as amorphous carbon or residual catalyst metal particles, etc. The plurality of carbon nanotubes of the super-aligned carbon nanotube array are joined together through van der Waals forces to form an array.

In another embodiment, the carbon nanotube structure is the carbon nanotube network structure. A plurality of meshes can be formed between carbon nanotubes in the carbon nanotube network structure, and a size of each of the plurality of meshes is in nanoscale or microscale. The carbon nanotube network structure can be but not limited to a carbon nanotube sponge, a carbon nanotube film structure, a carbon nanotube paper, or a network structure formed by woven or entangled a plurality of carbon nanotube wires.

The carbon nanotube sponge is a spongy carbon nanotube macroscopic structure formed by intertwining a plurality of carbon nanotubes, and the carbon nanotube sponge is a self-supporting porous structure.

Each of the plurality of carbon nanotube wires comprises a plurality of carbon nanotubes, and the plurality of carbon nanotubes are joined end to end through van der Waals forces to form a macroscopic wire structure. The carbon nanotube wire can be an untwisted carbon nanotube wire or a twisted carbon nanotube wire. The untwisted carbon nanotube wire comprises a plurality of carbon nanotubes substantially oriented along a length of the untwisted carbon nanotube wire. The twisted carbon nanotube wire comprises a plurality of carbon nanotubes spirally arranged along an axial direction of the twisted carbon nanotube wire. The twisted carbon nanotube wire can be formed by relatively rotating two ends of the untwisted carbon nanotube. During rotating the untwisted carbon nanotube wire, the plurality of carbon nanotubes of the untwisted carbon nanotube wire are arranged spirally along an axial direction and joined end to end by van der Waals force in an extension direction of the untwisted carbon nanotube wire, to form the twisted carbon nanotube wire.

The carbon nanotube film structure is formed by a plurality of carbon nanotube films stacked with each other, adjacent carbon nanotube films are combined by van der Waals forces, and a plurality of micro gaps between the carbon nanotubes of the carbon nanotube film structure.

The carbon nanotube film can be a drawn carbon nanotube film, a flocculated carbon nanotube film or a pressed carbon nanotube film.

The drawn carbon nanotube film includes a number of carbon nanotubes that are arranged substantially parallel to a surface of the drawn carbon nanotube film. A large number of the carbon nanotubes in the drawn carbon nanotube film can be oriented along a preferred orientation, meaning that a large number of the carbon nanotubes in the drawn carbon nanotube film are arranged substantially along the same direction. An end of one carbon nanotube is joined to another end of an adjacent carbon nanotube arranged substantially along the same direction, by van der Waals force, to form a free-standing film. The term ‘free-standing’ includes films that do not have to be supported by a substrate. The drawn carbon nanotube film can be formed by drawing from a carbon nanotube array. A width of the drawn carbon nanotube film relates to the carbon nanotube array from which the drawn carbon nanotube film is drawn. A thickness of the carbon nanotube drawn film can range from about 0.5 nanometers to about 100 micrometers. Examples of a drawn carbon nanotube film is taught by U.S. Pat. No. 7,992,616 to Liu et al., and US patent application US 2008/0170982 to Zhang et al. In one embodiment, the carbon nanotube film structure is formed by a plurality of drawn carbon nanotube films stacked and crossed with each other. There is a cross angle between the carbon nanotubes in the adjacent carbon nanotube drawn films, and the cross angle is greater 0 degrees and less than and equal to 90 degrees. Therefore, the carbon nanotubes in the plurality of drawn carbon nanotube films are interwoven to form a networked film structure.

The flocculated carbon nanotube film can include a number of carbon nanotubes entangled with each other. The carbon nanotubes can be substantially uniformly distributed in the flocculated carbon nanotube film. The flocculated carbon nanotube film can be formed by flocculating the carbon nanotube array. Examples of the flocculated carbon nanotube film are taught by U.S. Pat. No. 8,808,589 to Wang et al.

The pressed carbon nanotube film can include a number of disordered carbon nanotubes arranged along a same direction or along different directions. Adjacent carbon nanotubes are attracted to each other and combined by van der Waals force. A planar pressure head can be used to press the carbon nanotubes array along a direction perpendicular to the substrate, a pressed carbon nanotube film having a plurality of isotropically arranged carbon nanotubes can be obtained. A roller-shaped pressure head can be used to press the carbon nanotubes array along a fixed direction, a pressed carbon nanotube film having a plurality of carbon nanotubes aligned along the fixed direction is obtained. The roller-shaped pressure head can also be used to press the array of carbon nanotubes along different directions, a pressed carbon nanotube film having a plurality of carbon nanotubes aligned along different directions is obtained. Examples of the pressed carbon nanotube film are taught by U.S. Pat. No. 7,641,885 to Liu et al.

The carbon nanotube paper comprises a plurality of carbon nanotubes arranged substantially along a same direction, and the plurality of carbon nanotubes are joined end to end by van der Waals force in an extending direction, and the plurality of carbon nanotubes are substantially parallel to a surface of the carbon nanotube paper. Examples of the carbon nanotube paper are taught by U.S. Pat. No. 9,017,503 to Zhang et al.

Please referring to FIG. 1 again, the higher an energy of an electron beam, the greater a penetration depth in the porous carbon layer 200, on the contrary, the smaller the penetration depth. In one embodiment, the energy of the electron beams is less than or equal to 20 keV, and a thickness D of the porous carbon layer 200 is in a range from about 200 micrometers to about 600 micrometers, which is shown in FIG. 1. When the thickness of the porous carbon layer 200 is in the range of 200 micrometers to 600 micrometers, the electron beam does not easily penetrate the porous carbon layer 200 and be reflected from the porous carbon layer 200; and the porous carbon layer 200 has a high electron absorption rate. In one embodiment, the thickness of the porous carbon layer 200 is in a range from 300 micrometers to about 500 micrometers. In another embodiment, the thickness of the porous carbon layer 200 is in a range from 250 micrometers to about 400 micrometers.

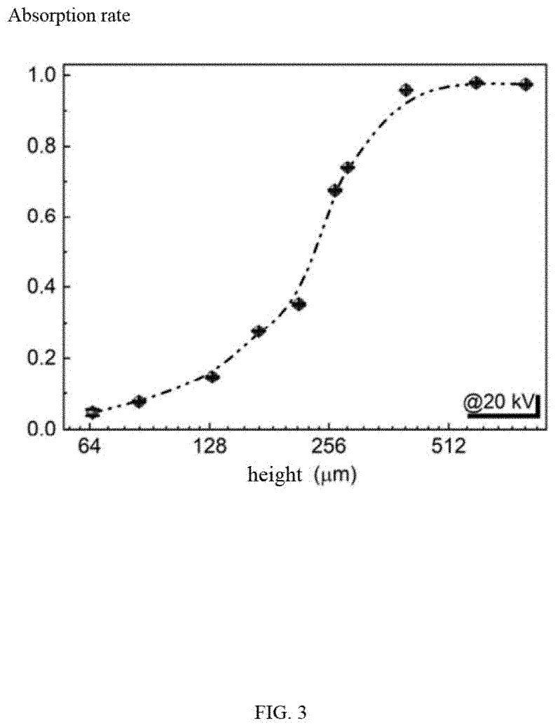

Referring to FIG. 3, when the porous carbon layer is a super-aligned carbon nanotube array, the electron absorption rate of the electron detector 10 varies with the height of the super-aligned carbon nanotube array. It can be seen from FIG. 3 that, as the height (which can also be regarded as the thickness of the porous carbon layer) of the super-aligned carbon nanotube array increases, the electron absorption rate of the electron detector 10 increases. When the height of the carbon nanotube array is about 500 microns, the electron absorption rate of the electron detector 10 is above 95%, which is basically close to 100%. When the height of the super-aligned carbon nanotube array exceeds 540 microns, as the height of the super-aligned carbon nanotube array continues to increase, and the electron absorption rate of the electron detector 10 is basically unchanged. When the porous carbon layer is the super-aligned carbon nanotube array, the height of the super-aligned carbon nanotube array is preferably in a range from 400 to 540 micrometers.

The electron absorbing element 100 further includes an insulating support 300, and the electronic blackbody material 200 is located on the surface of the insulating support 300. The insulating support 300 has a flat structure. The insulating support 300 can be a flexible or rigid substrate. For example, a material of the insulating support 300 can be glass, plastic, silicon wafer, silicon dioxide wafer, quartz wafer, poly methyl meth acrylate (PMMA), polyethylene terephthalate (PET), silicon, silicon with an oxide layer, quartz, etc. A size of the substrate can be set according to actual needs. In this embodiment, the electronic blackbody material 200 is located on a surface of a silicon substrate. The insulating support 300 is an optional structure. When the electronic blackbody material 200 is a free-standing structure, the insulating substrate can be omitted.

When an electron beam including a plurality of electrons irradiates the surface of the electronic blackbody material 200, the energy of the electron beam is completely absorbed by the electronic blackbody material 200 to produce charges inside the electronic blackbody material. The electron detecting element 102 is configured to test the charges generated in the electronic blackbody material 200 and perform numerical conversion to form an electrical signal. The electron detecting element 102 can be an ammeter or a voltmeter. Since the electron blackbody material 200 can almost completely absorb the energy of the electron beam, the charges value measured by the electron detecting element 102 can directly reflect the energy of the electron beam. In this embodiment, the electron detecting element 102 is an ammeter used to test a current value generated by the charges in the electronic blackbody material 200.

The present invention proposes that a porous carbon layer is used as an electronic blackbody material for the first time. When electrons hit the electronic blackbody material, the electrons will be refracted and reflected multiple times between the micro gaps in the porous carbon layer, and cannot be emitted from the porous carbon layer. At this time, the electron absorption rate of the porous carbon layer can reach more than 99.99%, which can almost reach 100%, and the porous carbon layer can be regarded as an absolute blackbody of electrons. The present invention can realize 100% absorption of electrons through a simple porous carbon layer without complicated design. Moreover, the porous carbon layer has a lower cost, which greatly reduces costs of such electronic devices. When a traditional Faraday cup is used to absorb electrons, a cross-section of the electron beam cannot be very large due to a limitation of a size of the cup mouth. However, with the porous carbon layer of the present invention, a surface area of the porous carbon layer used for absorbing electrons can be adjusted according to the cross-sectional area of the electron beam. Therefore, the electron blackbody material and the electron detector provided by the present invention have more advantages. The electron blackbody material or the electron detector has a wide range of applications and a greater application prospect.

It is to be understood that the above-described embodiments are intended to illustrate rather than limit the present disclosure. Variations may be made to the embodiments without departing from the spirit of the present disclosure as claimed.

Elements associated with any of the above embodiments are envisioned to be associated with any other embodiments. The above-described embodiments illustrate the scope of the present disclosure but do not restrict the scope of the present disclosure.

Depending on the embodiment, certain of the steps of a method described may be removed, others may be added, and the sequence of steps may be altered. The description and the claims drawn to a method may include some indication in reference to certain steps. However, the indication used is only to be viewed for identification purposes and not as a suggestion as to an order for the steps.

What is claimed is:

1. An electron blackbody material, comprising:
a porous carbon layer, wherein the porous carbon layer consists of a plurality of carbon material particles and a plurality of micro gaps, the plurality of micro gaps are defined between the plurality of carbon material particles.

2. The electron blackbody material of claim 1, wherein the carbon material particles are made of pure carbon atoms.

3. The electron blackbody material of claim 1, wherein the plurality of carbon material particles comprise at least one of linear particles and spherical particles.

4. The electron blackbody material of claim 3, wherein a diameter of a cross section of each of the linear particles is less than or equal to 1000 micrometers, and a diameter of each of the spherical particles is less than or equal to 1000 micrometers.

5. The electron blackbody material of claim 3, wherein the linear particles are carbon fibers, carbon micron-wires, or carbon nanotubes.

6. The electron blackbody material of claim 1, wherein the porous carbon layer is a carbon nanotube array or a carbon nanotube network structure.

7. The electron blackbody material of claim 6, wherein the carbon nanotube network structure is a carbon nanotube sponge, a carbon nanotube film structure, a carbon nanotube paper, or a network structure comprising a plurality of carbon nanotube wires woven or entangled with each other.

8. The electron blackbody material of claim 1, wherein a thickness of the porous carbon layer is in a range from 200 micrometers to 600 micrometers.

9. The electron blackbody material of claim 1, wherein the porous carbon layer is a super-aligned carbon nanotube array, and a height of the super-aligned carbon nanotube array is in a range from 350 micrometers to 600 micrometers.

10. The electron blackbody material of claim 1, further comprising a substrate, wherein the porous carbon layer is on the substrate.

11. An electron detector comprising:
an electron absorbing element comprising a porous carbon layer, wherein the porous carbon layer consists of a plurality of carbon material particles and a plurality of micro gaps, the plurality of micro gaps are between the plurality of carbon material particles; and
an electron detecting element comprising a first terminal and a second terminal, the first terminal is electrically connected to the electron absorbing element, the second terminal is grounded.

12. The electron detector of claim 11, wherein the plurality of carbon material particles are carbon fibers, carbon micron-wires, carbon nanotubes, carbon nanospheres or carbon microspheres.

13. The electron detector of claim 11, wherein the porous carbon layer is a carbon nanotube array or a carbon nanotube network structure.

14. The electron detector of claim 13, wherein the carbon nanotube network structure is a carbon nanotube sponge, a carbon nanotube film structure, a carbon nanotube paper, or a network structure comprising a plurality of carbon nanotube wires woven or entangled with each other.

15. The electron detector of claim 11, wherein the porous carbon layer is a super-aligned carbon nanotube array, and a height of the super-aligned carbon nanotube array is in a range from 350 micrometers to 600 micrometers.
